(19) United States
(12) Patent Application Publication
(10) Pub. No.: US 2024/0007056 A1
(43) Pub. Date: Jan. 4, 2024

(54) CIRCUIT AND METHOD FOR PROTECTING POWER AMPLIFIER

(71) Applicant: SMARTER MICROELECTRONICS (GUANG ZHOU) CO., LTD., Guangzhou (CN)

(72) Inventors: Yangyang PENG, Guangzhou (CN); Yang HOU, Guangzhou (CN)

(73) Assignee: SMARTER MICROELECTRONICS (GUANG ZHOU) CO., LTD., Guangzhou (CN)

(21) Appl. No.: 18/468,709

(22) Filed: Sep. 16, 2023

Related U.S. Application Data
(63) Continuation of application No. PCT/CN2022/129898, filed on Nov. 4, 2022.

(30) Foreign Application Priority Data
Nov. 5, 2021 (CN) 202111307062.3

(51) Int. Cl. H03F 1/52; H03F 3/21

(52) U.S. Cl. CPC H03F 1/52; H03F 3/21; H03F 2200/426

(57) ABSTRACT

A circuit for protecting a power amplifier includes a protection control circuit, an inter-stage adjustment circuit and a multi-stage power amplification circuit. The inter-stage adjustment circuit is connected in series between at least two adjacent power amplification circuits in the multi-stage power amplification circuit. The protection control circuit is configured to: control the inter-stage adjustment circuit to be in a turn-off state when overload protection of any stage power amplification circuit is enabled; and control the inter-stage adjustment circuit to be in a turn-on state, after a preset time elapses from the overload protection of the power amplification circuit being closed. In this way, damage of the power amplifier due to excessive input power may be avoided by the inter-stage adjustment circuit, thereby achieving a function of protecting the power amplifier.

### CROSS-REFERENCE TO RELATED APPLICATIONS

This is a continuation of International Application No. PCT/CN2022/129898 filed on Nov. 4, 2022, which claims priority to Chinese Patent Application No. 202111307062.3 filed on Nov. 5, 2021. The disclosures of the above-referenced applications are hereby incorporated by reference in their entirety.

### BACKGROUND

Power Amplifier (PA) has a function of amplifying power of a signal, has a high operation power, requires a large voltage and current, and is easy to be burnt out when it is operated improperly. In order to enhance reliability of PA, overvoltage and overcurrent protection circuits are usually added in circuit design. When overvoltage and overcurrent occur, a bias current of PA is reduced or even cut off to achieve the purpose of protecting PA.

### SUMMARY

When overvoltage protection or overcurrent protection is performed on PA, decrease of system gain leads to increase of an input signal. In this way, when voltage protection or current protection is removed, PA may immediately return to a normal operation state, and there may be uncertain states in a process of PA returning to the normal operation state and establishing a bias. At this time, since the input signal has large power, PA may be burnt out due to a large input power at the moment of recovering establishment of a path.

The disclosure relates to the technical field of power amplifiers, and in particular to a circuit and method for protecting a power amplifier.

The disclosure provides a circuit and method for protecting a power amplifier, which may avoid damage of the power amplifier due to excessive input power, thereby achieving a function of protecting the power amplifier.

Technical solutions of the disclosure are realized as follows.

According to a first aspect, an embodiment of the disclosure provides a circuit for protecting a power amplifier, including a protection control circuit, an inter-stage adjustment circuit and a multi-stage power amplification circuit. The inter-stage adjustment circuit is connected in series between at least two adjacent power amplification circuits in the multi-stage power amplification circuit.

The protection control circuit is configured to:
control the inter-stage adjustment circuit to be in a turn-off state when overload protection of any stage power amplification circuit is enabled; and
control the inter-stage adjustment circuit to be in a turn-on state, after a preset time elapses from the overload protection of the power amplification circuit being closed.

In some embodiments, the inter-stage adjustment circuit may be arranged between at least last two stage power amplification circuits in the multi-stage power amplification circuit.

In some embodiments, the inter-stage adjustment circuit may be arranged between every two adjacent stage power amplification circuits in the multi-stage power amplification circuit.

In some embodiments, the protection control circuit may include a controller and an overload detection circuit.

The overload detection circuit is configured to output an overload signal and send the overload signal to the controller, when overload of a target power amplification circuit is detected.

The controller is configured to send a protection signal to the target power amplification circuit when the overload signal is received, to enable overload protection of the target power amplification circuit.

In some embodiments, the protection signal may be configured to instruct the target power amplification circuit to perform at least one of:
reducing a direct current (DC) operation point of a power amplifier in the target power amplification circuit; or
turning off the power amplifier in the target power amplification circuit.

In some embodiments, the target power amplification circuit may include at least one power amplifier.

The overload detection circuit is specifically configured to detect index of the power amplifier in the target power amplification circuit, and determine overload of the target power amplification circuit when index of any power amplifier in the target power amplification circuit is detected to be greater than a preset index threshold.

Here, the index includes a bias voltage of the power amplifier or an operation current of the power amplifier.

In some embodiments, the overload detection circuit may include an overvoltage detection circuit.

The overvoltage detection circuit is configured to compare the bias voltage of the power amplifier in the target power amplification circuit with a preset voltage threshold, and send an overvoltage signal to the controller when the bias voltage is greater than the preset voltage threshold.

The controller is specifically configured to send a first protection signal to the target power amplification circuit when the overvoltage signal is received, here, the first protection signal is configured to indicate overvoltage of the target power amplification circuit, so as to enable the overload protection of the target power amplification circuit.

In some embodiments, the overload detection circuit may include an overcurrent detection circuit.

The overcurrent detection circuit is configured to compare the operation current of the power amplifier in the target power amplification circuit with a preset current threshold, and send an overcurrent signal to the controller when the operation current is greater than the preset current threshold.

The controller is specifically configured to send a second protection signal to the target power amplification circuit when the overcurrent signal is received, here, the second protection signal is configured to indicate overcurrent of the target power amplification circuit, so as to enable the overload protection of the target power amplification circuit.

In some embodiments, the controller may be further configured to send a recovery signal to the target power amplification circuit, to close the overload protection of the target power amplification circuit.

Here, the recovery signal is configured to instruct the target power amplification circuit to perform at least one of:
recovering a DC operation point of a power amplifier in the target power amplification circuit; or
turning on the power amplifier in the target power amplification circuit.

In some embodiments, the preset time may indicate a delay time required for each device in the circuit for protecting the power amplifier to reach a steady state, after the overload protection of the power amplification circuit is closed.

In some embodiments, the protection control circuit may be further configured to control the inter-stage adjustment circuit to be in the turn-on state during normal operation of the circuit for protecting the power amplifier.

In some embodiments, the inter-stage adjustment circuit may be an inter-stage switch circuit or an adjustable attenuation network module.

In some embodiments, the inter-stage adjustment circuit may be the inter-stage switch circuit, and the inter-stage switch circuit may include a switch.

Here, the protection control circuit is specifically configured to:
control the switch to be turned off when overload protection of a target power amplification circuit is enabled, such that the inter-stage adjustment circuit is in the turn-off state; and
control the switch to be turned on, after a preset time elapses from the overload protection of the target power amplification circuit being closed, such that the inter-stage adjustment circuit is in the turn-on state.

In some embodiments, the inter-stage adjustment circuit may be the adjustable attenuation network module, and the adjustable attenuation network module may be configured to characterize a state change of the inter-stage adjustment circuit by adjusting an insertion loss itself.

Here, the protection control circuit is specifically configured to:
control the insertion loss of the adjustable attenuation network module to be in a first insertion loss state when overload protection of a target power amplification circuit is enabled, such that the inter-stage adjustment circuit is in the turn-off state; and
control the insertion loss of the adjustable attenuation network module to be in a second insertion loss state, after a preset time elapses from the overload protection of the target power amplification circuit being closed, such that the inter-stage adjustment circuit is in the turn-on state.

Here, the insertion loss in the first insertion loss state is greater than the insertion loss in the second insertion loss state.

According to a second aspect, an embodiment of the disclosure provides a method for protecting a power amplifier, the method includes the following operations.

A protection control circuit controls an inter-stage adjustment circuit to be in a turn-off state when overload protection of any stage power amplification circuit is enabled.

The protection control circuit controls the inter-stage adjustment circuit to be in a turn-on state, after a preset time elapses from the overload protection of the power amplification circuit being closed.

According to the circuit and method for protecting the power amplifier provided in the embodiments of the disclosure, the circuit for protecting the power amplifier includes a protection control circuit, an inter-stage adjustment circuit and a multi-stage power amplification circuit. The inter-stage adjustment circuit is connected in series between at least two adjacent power amplification circuits in the multi-stage power amplification circuit. The protection control circuit is configured to: control the inter-stage adjustment circuit to be in a turn-off state when overload protection of any stage power amplification circuit is enabled; and control the inter-stage adjustment circuit to be in a turn-on state, after a preset time elapses from the overload protection of the power amplification circuit being closed. In this way, it is ensured that the power amplifier may not be damaged due to excessive input power in a process of establishing a steady state of the circuit, and that incoming of the input signal may not burn out the power amplifier after the circuit returns to the steady state, such that damage of the power amplifier due to excessive input power is avoided, thereby achieving a function of protecting the power amplifier.

### BRIEF DESCRIPTION OF THE DRAWINGS

FIG. 1 is a schematic diagram of compositional structures of a power amplification circuit including an overvoltage protection circuit.

FIG. 2 is a schematic diagram of compositional structures of a power amplification circuit including an overcurrent protection circuit.

FIG. 3 is a first schematic diagram of compositional structures of a circuit for protecting a power amplifier according to an embodiment of the disclosure.

FIG. 4 is a second schematic diagram of compositional structures of a circuit for protecting a power amplifier according to an embodiment of the disclosure.

FIG. 5 is a first schematic diagram of circuit structures of a circuit for protecting a power amplifier according to an embodiment of the disclosure.

FIG. 6 is a second schematic diagram of circuit structures of a circuit for protecting a power amplifier according to an embodiment of the disclosure.

FIG. 7 is a third schematic diagram of circuit structures of a circuit for protecting a power amplifier according to an embodiment of the disclosure.

FIG. 8 is a fourth schematic diagram of circuit structures of a circuit for protecting a power amplifier according to an embodiment of the disclosure.

FIG. 9 is a fifth schematic diagram of circuit structures of a circuit for protecting a power amplifier according to an embodiment of the disclosure.

FIG. 10 is a sixth schematic diagram of circuit structures of a circuit for protecting a power amplifier according to an embodiment of the disclosure.

FIG. 11 is a schematic flowchart of a method for protecting a power amplifier according to an embodiment of the disclosure.

FIG. 12 is a schematic diagram of compositional structures of an electronic device according to an embodiment of the disclosure.

### DETAILED DESCRIPTION

Technical solutions in the embodiments of the disclosure will be clearly and completely described in detail below in combination with the drawings in the embodiments of the disclosure. It may be understood that specific embodiments described here are only intended to explain relevant applications, rather than limiting the applications. Furthermore, it should also be noted that for ease of description, only portions related to the relevant applications are shown in the drawings.

Unless otherwise defined, all technical and scientific terms used here have the same meaning as usually understood by technicians in the technical field to which the disclosure belongs. Terms used here is for the purpose of describing the embodiments of the disclosure only and is not intended to limit the disclosure.

In the following descriptions, reference is made to “some embodiments” which describe a subset of all possible embodiments. However, it may be understood that “some embodiments” may be the same or different subsets of all possible embodiments and may be combined with each other without conflict.

It should be pointed out that terms “first\second\third” used in embodiments of the disclosure are only intended to distinguish similar objects, without representing a specific order of the objects. It may be understood that the terms “first\second\third” may be interchanged in a specific order or sequence where permissible, to enable the embodiments of the disclosure described here to be implemented in an order other than that illustrated or described here.

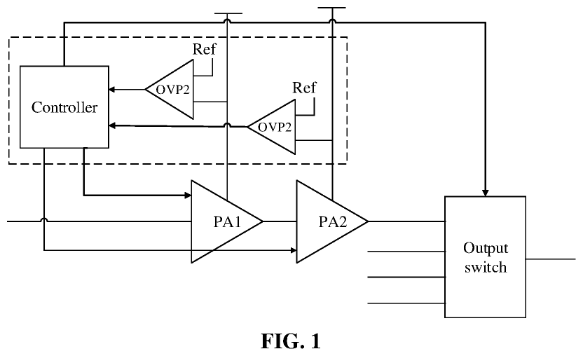

In order to enhance reliability of a power amplifier, overvoltage and overcurrent protection circuits are usually added in circuit design. With reference to FIG. 1, a schematic diagram of compositional structures of a power amplification circuit including an overvoltage protection circuit is shown. As shown in FIG. 1, the power amplification circuit includes a controller, an overvoltage protection circuit OVP1, an overvoltage protection circuit OVP2, a first power amplifier PA1, a second power amplifier PA2, and an output switch. In application, OVP1 compares a bias voltage of the first power amplifier PA1 with a reference voltage (Ref). When an excessive bias voltage occurs during application of the first power amplifier PA1, OVP1 provides a comparison signal to the controller, and the controller limits power of the first power amplifier PA1, thereby achieving a function of protecting the first power amplifier PA1. The same principle applies to protection of the second power amplifier PA2, which is not elaborated here.

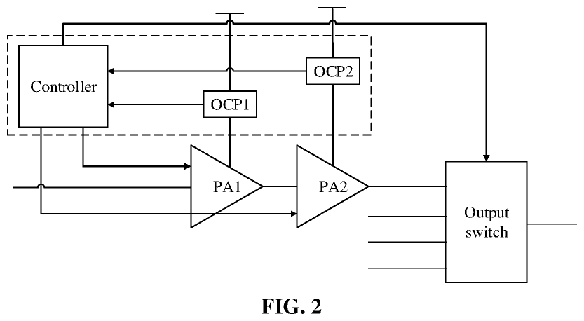

With reference to FIG. 2, a schematic diagram of compositional structures of a power amplification circuit including an overcurrent protection circuit is shown. As shown in FIG. 2, the power amplification circuit includes a controller, an overcurrent protection circuit OCP1, an overcurrent protection circuit OCP2, a first power amplifier PA1, a second power amplifier PA2, and an output switch. In application, OCP1 compares an operation current of the first power amplifier PA1. When an excessive current occurs during application of the first power amplifier PA1, OCP1 provides a signal to the controller, and the controller limits power of the first power amplifier PA1, thereby achieving a function of protecting the first power amplifier PA1. The same principle applies to protection of the second power amplifier PA2, which is not elaborated here.

In the power amplification circuits shown in FIG. 1 and FIG. 2 (FIG. 1 and FIG. 2 are only examples, placement positions and implementations of the overvoltage and overcurrent protection circuits may be different in actual applications), after voltage protection or current protection is enabled, output power of the power amplification circuit may become low. At this time, under control of power of the system, the system may continuously push up input power of the power amplifier to make the output power close to the original target value as much as possible. Since a gain of the power amplifier is relatively low at this time, the input power may be locked at a relatively high power.

When the voltage protection or current protection is removed at this time, the power amplifier may immediately return to a normal operation state, that is, return to have a large gain and a large current. However, there may be uncertain states in a process of establishing an entire radio frequency (RF) path to a steady state, for example, a process of establishing bias of the power amplifier is uncertain, a switch on the RF path may not be fully opened, load of the power amplifier is not a certain impedance, or the like. At this time, when a large input signal is input, the power amplifier may be broken due to a large input power at the moment of recovering establishment of the path, especially for a final stage power amplifier, it is easier to be damaged since it receives a signal amplified by previous stage power amplifiers.

In view of this, an embodiment of the disclosure provides a circuit for protecting a power amplifier, including a protection control circuit, an inter-stage adjustment circuit and a multi-stage power amplification circuit. The inter-stage adjustment circuit is connected in series between at least two adjacent power amplification circuits in the multi-stage power amplification circuit. Here, the protection control circuit is configured to: control the inter-stage adjustment circuit to be in a turn-off state when overload protection of any stage power amplification circuit is enabled; and control the inter-stage adjustment circuit to be in a turn-on state, after a preset time elapses from the overload protection of the power amplification circuit being closed. In this way, since the inter-stage adjustment circuit is turned off when the overload protection is performed on the power amplification circuit, and the inter-stage adjustment circuit is turned on after a preset time elapses from the overload protection being closed, thereby ensuring that the power amplifier may not be damaged due to excessive input power in a process of returning to a steady normal operation state of the circuit for protecting the power amplifier, while ensuring that incoming of the input signal may not burn out the power amplifier after the circuit returns to the steady state, such that damage of the power amplifier due to excessive input power is avoided, thereby achieving a function of protecting the power amplifier.

Embodiments of a circuit for protecting a power amplifier having a two-stage power amplification circuit will be described in detail below with reference to the drawings. It should be noted that the circuit for protecting the power amplifier of the disclosure may also have more stages of power amplification circuits, and a protection principle thereof is consistent with that of the two-stage power amplification circuit.

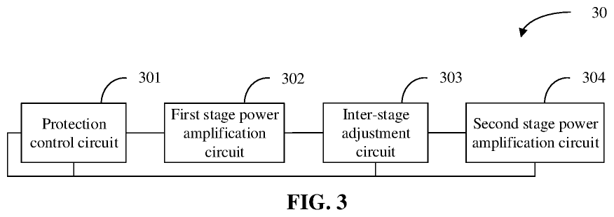

In an embodiment of the disclosure, with reference to FIG. 3, a first schematic diagram of compositional structures of a circuit 30 for protecting a power amplifier according to an embodiment of the disclosure is shown. As shown in FIG. 3, the circuit 30 for protecting the power amplifier may include a protection control circuit 301, a first stage power amplification circuit 302, an inter-stage adjustment circuit 303 and a second stage power amplification circuit 304. The inter-stage adjustment circuit 303 is connected in series between the first stage power amplification circuit 302 and the second stage power amplification circuit 304.

The protection control circuit 301 is configured to:
control the inter-stage adjustment circuit 303 to be in a turn-off state when overload protection of the first stage power amplification circuit 302 or the second stage power amplification circuit 304 is enabled; and
control the inter-stage adjustment circuit 303 to be in a turn-on state, after a preset time elapses from the overload protection of the first stage power amplification circuit 302 or the second stage power amplification circuit 304 being closed.

It should be noted that the circuit 30 for protecting the power amplifier provided in the embodiment of the disclosure may be used to prevent a phenomenon where the power amplifier is burnt out due to excessive input power at a final stage. In the embodiment of the disclosure, the circuit 30 for protecting the power amplifier may be applied to an electronic device including a power amplifier. Here, for example, the electronic device may be a computer, a smart phone, a tablet computer, a laptop computer, a palmtop computer, a personal digital assistant (PDA), a navigation device, or the like, which is not specifically limited in the embodiment of the disclosure.

It should also be noted that the first stage power amplification circuit and the second stage power amplification circuit may also refer to any two stage power amplification circuits in the circuit for protecting the power amplifier. For example, when the circuit for protecting the power amplifier includes a three-stage power amplification circuit, the first stage power amplification circuit may be an amplification circuit connected to an input end of the circuit for protecting the power amplifier, and the second stage power amplification circuit may be a final stage power amplification circuit. As another example, when the circuit for protecting the power amplifier includes a three-stage power amplification circuit, the first stage power amplification circuit is a power amplification circuit located at the middle, and the second stage power amplification circuit is a final stage power amplification circuit.

In some embodiments, when the circuit for protecting the power amplifier includes a multi-stage power amplification circuit, the inter-stage adjustment circuit may be arranged between every two adjacent stage power amplification circuits, or between only part of the power amplification circuits. For example, when there are three or more stage power amplification circuits, inter-stage adjustment circuits are arranged between adjacent power amplification circuits in the multi-stage power amplification circuits respectively.

In some embodiments, when the circuit for protecting the power amplifier includes a multi-stage power amplification circuit, the inter-stage adjustment circuit is arranged between at least last two stage power amplification circuits in the multi-stage power amplification circuit. For example, when there are three stage power amplification circuits, the inter-stage adjustment circuit is arranged between the second stage power amplification circuit and the third stage power amplification circuit.

It should also be noted that the embodiment of the disclosure mainly takes the circuit for protecting the power amplifier including a two-stage power amplification circuit, i.e., the first stage power amplification circuit and the second stage power amplification circuit as an example for exemplary description. The inter-stage adjustment circuit 303 is connected in series between the first stage power amplification circuit 302 and the second stage power amplification circuit 304, here, the inter-stage adjustment circuit 303 may be an inter-stage switch circuit or an adjustable attenuation network module.

In some embodiments, when the inter-stage adjustment circuit 303 is the inter-stage switch circuit, the inter-stage switch circuit includes a switch.

Here, the protection control circuit 301 is specifically configured to:
control the switch to be turned off when overload protection of the first stage power amplification circuit 302 or the second stage power amplification circuit 304 is enabled, such that the inter-stage adjustment circuit 303 is in the turn-off state; and
control the switch to be turned on, after a preset time elapses from the overload protection of the first stage power amplification circuit 302 or the second stage power amplification circuit 304 being closed, such that the inter-stage adjustment circuit 303 is in the turn-on state.

It should be noted that when the inter-stage adjustment circuit 303 is an inter-stage switch circuit, the inter-stage switch circuit may include one or more switches, and the way by which turn-off and turn-on states of the inter-stage adjustment circuit 303 are controlled by the protection control circuit 301 may be: directly turning on or off the switches in the inter-stage switch circuit.

It should also be noted that in the embodiment of the disclosure, when the overload protection of any one or more stage power amplification circuits in the multi-stage (two or more stages) power amplification circuit is enabled or closed, any one or more stage power amplification circuits as mentioned above may be referred to as target power amplification circuit(s). In subsequent descriptions, since the first stage power amplification circuit and the second stage power amplification circuit are taken as an example for description, the target power amplification circuit mainly refers to the first stage power amplification circuit and/or the second stage power amplification circuit.

In some embodiments, when the inter-stage adjustment circuit 303 is the adjustable attenuation network module, the adjustable attenuation network module is configured to characterize a state change of the inter-stage adjustment circuit by adjusting an insertion loss itself.

Here, the protection control circuit 301 is specifically configured to:
control the insertion loss of the adjustable attenuation network module to be in a first insertion loss state when overload protection of the first stage power amplification circuit 302 or the second stage power amplification circuit 304 is enabled, such that the inter-stage adjustment circuit 303 is in the turn-off state; and
control the insertion loss of the adjustable attenuation network module to be in a second insertion loss state, after a preset time elapses from the overload protection of the first stage power amplification circuit 302 or the second stage power amplification circuit 304 being closed, such that the inter-stage adjustment circuit 303 is in the turn-on state.

Here, the insertion loss in the first insertion loss state is greater than the insertion loss in the second insertion loss state.

It should be noted that when the inter-stage adjustment circuit 303 is an adjustable attenuation network module, the adjustable attenuation network module includes one or more adjustable attenuation networks, and the adjustable attenuation network module may adjust the insertion loss itself according to an adjustment signal sent by the protection control circuit 301.

Specifically, the way by which turn-off and turn-on states of the inter-stage adjustment circuit 303 are controlled by the protection control circuit 301 may be: when it is required to control the inter-stage adjustment circuit 301 to be in the turn-off state, the adjustable attenuation network module is adjusted to be in the first insertion loss state, here, the first insertion loss state is a high insertion loss state, that is, almost all the power of signal passing through the inter-stage adjustment circuit 303 is consumed at this time, such that the inter-stage adjustment circuit 303 is in the turn-off state.

Furthermore, when it is required to control the inter-stage adjustment circuit 301 to be in the turn-on state, the adjustable attenuation network module is adjusted to be in the second insertion loss state, here, the second insertion loss state is a low insertion loss state, that is, the insertion loss in the first insertion loss state is greater than the insertion loss in the second insertion loss state. At this time, since the adjustable attenuation network module is in the low insertion loss state, power loss is small, the signal may normally pass through the inter-stage adjustment circuit 303, such that the inter-stage adjustment circuit 303 is in the turn-on state.

That is, when the inter-stage adjustment circuit 303 is the adjustable attenuation network module, the first insertion loss state is usually an insertion loss state where almost all the power of the signal is consumed, and the second insertion loss state is usually an insertion loss state where the signal may normally pass through the inter-stage adjustment circuit for transmission.

When the protection control circuit includes multiple adjustment circuits, each of the multiple adjustment circuits may be either the adjustable attenuation network module or the inter-stage switch circuit, or part of the multiple adjustment circuits may be the adjustable attenuation network module and part of the multiple adjustment circuits may be the inter-stage switch circuit.

It should also be noted that in the embodiment of the disclosure, the first stage power amplification circuit 302, the second stage power amplification circuit 304 and the inter-stage adjustment circuit 303 are controlled by the protection control circuit 301, and when overload of the first stage power amplification circuit 302 or the second stage power amplification circuit 304 (here, overload mainly refers to overcurrent or overvoltage) occurs, the overload protection of the first stage power amplification circuit 302 or the second stage power amplification circuit 304 is enabled, while the inter-stage adjustment circuit 303 is controlled to be in the turn-off state. Exemplarily, the protection control circuit 301 may send an adjustment signal indicating turn-off to the inter-stage adjustment circuit 303, and the inter-stage adjustment circuit 303 may adjust to be in the turn-off state after receiving the adjustment signal.

Furthermore, there is a possibility that overload of the first stage power amplification circuit 302 and the second stage power amplification circuit 304 occur simultaneously. At this time, overload protections of the first stage power amplification circuit 302 and the second stage power amplification circuit 304 are enabled simultaneously, and the inter-stage adjustment circuit 303 is controlled to be in the turn-off state. That is, when overload protection of any power amplification circuit of the circuit 30 for protecting the power amplifier is enabled, the inter-stage adjustment circuit 303 may be turned off.

At this time, since the overload protection of the first stage power amplification circuit 302 or the second stage power amplification circuit 304 is enabled and the inter-stage adjustment circuit 303 is in the turn-off state, gain of the whole circuit may decrease, and the second stage power amplification circuit 304 may not receive a signal transmitted by a previous stage power amplification circuit and may not send the signal outward. Taking a mobile phone as an example, a base station may not receive signals of the mobile phone at this time, and may send commands to the mobile phone, which makes power of the input signal input to the circuit 30 for protecting the power amplifier increased continuously, that is, there is a large input power at this time.

When overload of the first stage power amplification circuit 302 or the second stage power amplification circuit 304 no longer occurs, the protection control circuit 301 may turn off the overload protection of the first stage power amplification circuit 302 or the second stage power amplification circuit 304, and then control the inter-stage adjustment circuit 303 to be in the turn-on state after a preset time elapses. Exemplarily, the protection control circuit 301 may send an adjustment signal indicating turn-on to the inter-stage adjustment circuit 303, and the inter-stage adjustment circuit 303 may be turned on after receiving the adjustment signal, to remain in the turn-on state.

When the inter-stage adjustment circuit 303 is not arranged between the first stage power amplification circuit 302 and the second stage power amplification circuit 304, then after the overload protection is closed, power of the input signal is very high due to closed-loop control. When the whole circuit immediately returns to a normal operation state at this time, because power of the input signal is too large, it may be even larger after being amplified by a previous stage power amplification circuit. When the signal is transmitted to the second stage power amplification circuit 304, the power amplifier in the second stage power amplification circuit 304 is likely to be burned out by the signal with excessive power.

While in the embodiment of that disclosure, when the overload protection of the first stage power amplification circuit 302 or the second stage power amplification circuit 304 is closed, the inter-stage adjustment circuit 303 is still in the turn-off state. At this time, even though the input signal has large power, since the inter-stage adjustment circuit 303 is in the turn-off state, the second stage power amplification circuit 304 after the inter-stage adjustment circuit 303 may not bear the signal with large power. Although the circuit is still in an unsteady state stage during a period when the overload protection is closed and the steady state of the circuit 30 for protecting the power amplifier is established, the power amplifier in the power amplification circuit may not be burned out since the second stage power amplification circuit 304 is not required to bear the signal with large power.

After the overload protection is closed and a preset time elapses, the protection control circuit 301 controls the inter-stage adjustment circuit 303 to be in the turn-on state again. Here, the preset time indicates a delay time required for each device in the circuit 30 for protecting the power amplifier to reach a steady state, after the overload protection of the first stage power amplification circuit 302 or the second stage power amplification circuit 304 is closed.

At this time, the power amplifier and other devices in the whole circuit have reached their respective steady states. Since the steady state of the circuit has been established at this time, incoming of the input signal with normal power may not burn out the power amplifier in the power amplification circuit.

In other embodiments, the preset time may be 85% to 95% of the time required to reach the steady state, or 105% to 110% of the time required to reach the steady state.

In some embodiments, the protection control circuit 301 is further configured to control the inter-stage adjustment circuit 303 to be in the turn-on state during normal operation of the circuit 30 for protecting the power amplifier.

It should be noted that when the circuit 30 for protecting the power amplifier is in the normal operation state, the protection control circuit 301 controls the inter-stage adjustment circuit 303 to be in the turn-on state, such that the signal may normally pass through the inter-stage adjustment circuit 303 to reach the second stage power amplification circuit 304.

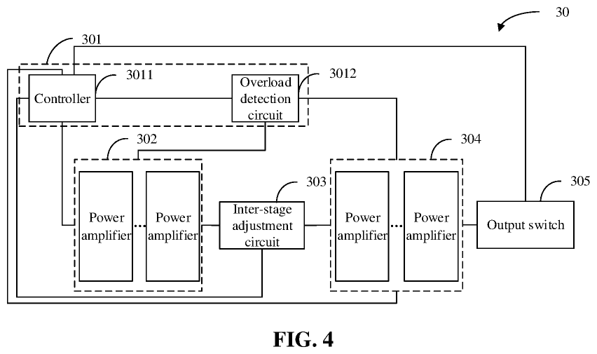

Furthermore, in some embodiments, with reference to FIG. 4, a second schematic diagram of compositional structures of a circuit 30 for protecting a power amplifier according to an embodiment of the disclosure is shown. As shown in FIG. 4, the protection control circuit 301 may include a controller 3011 and an overload detection circuit 3012.

The overload detection circuit 3012 is configured to output an overload signal and send the overload signal to the controller 3011, when overload of a target power amplification circuit is detected.

The controller 3011 is configured to send a protection signal to the target power amplification circuit when the overload signal is received, to enable overload protection of the target power amplification circuit.

Here, the target power amplification circuit is the first stage power amplification circuit 302 or the second stage power amplification circuit 304.

It should be noted that the protection control circuit 301 may specifically include the controller 3011 and the overload detection circuit 3012. The overload detection circuit 3012 detects the first stage power amplification circuit 302 and the second stage power amplification circuit 304 to determine whether overload of the first stage power amplification circuit 302 and the second stage power amplification circuit 304 occur. The power amplification circuit subjected to detection is referred to as the target power amplification circuit, that is, the target power amplification circuit is the first stage power amplification circuit 302 or the second stage power amplification circuit 304.

The overload detection circuit 3012 outputs the overload signal and send the overload signal to the controller 3011, when overload of the target power amplification circuit is detected. The controller 3011 sends the protection signal to the target power amplification circuit when the overload signal is received, to enable the overload protection of the target power amplification circuit.

Furthermore, for manners of overload protection of the target power amplification circuit, in some embodiments, the protection signal is configured to instruct the target power amplification circuit to perform at least one of:
reducing a DC operation point of a power amplifier in the target power amplification circuit; or
turning off the power amplifier in the target power amplification circuit.

It should be noted that the protection signal is configured to instruct enabling the overload protection of the target power amplification circuit, specifically, the protection signal may instruct the target power amplification circuit to perform: reducing the DC operation point of the power amplifier in the target power amplification circuit; or turning off the power amplifier in the target power amplification circuit, to implement the overload protection of the target power amplification circuit.

Furthermore, as shown in FIG. 4, the circuit for protecting the power amplifier may further include an output switch 305, the controller 3011 may also control the output switch 305 to be turned on or off. In this way, the controller 3011 may also control the output switch 305 to be in a turn-off state when the overload protection of the target power amplification circuit is enabled.

Furthermore, when overload of the first stage power amplification circuit 302 or the second stage power amplification circuit 304 no longer occurs, it is also required to recover normal operation of the circuit 30 for protecting the power amplifier. Therefore, in some embodiments, the controller 3011 is further configured to send a recovery signal to the target power amplification circuit, to close the overload protection of the target power amplification circuit.

Here, the recovery signal is configured to instruct the target power amplification circuit to perform at least one of:
recovering a DC operation point of a power amplifier in the target power amplification circuit; or
turning on the power amplifier in the target power amplification circuit.

It should be noted that the recovery signal is configured to instruct closing the overload protection of the target power amplification circuit, specifically, the recovery signal may instruct the target power amplification circuit to perform: recovering the DC operation point of the power amplifier in the target power amplification circuit; or turning on the power amplifier in the target power amplification circuit, to close the overload protection of the target power amplification circuit. Furthermore, when the output switch in the circuit is turned off during the overload protection, the controller may also control the output switch 305 to be in a turn-on state.

In some embodiments, with reference to FIG. 4, the target power amplification circuit includes at least one power amplifier.

The overload detection circuit 3012 is specifically configured to detect index of the power amplifier in the target power amplification circuit, and determine overload of the target power amplification circuit when index of any power amplifier in the target power amplification circuit is detected to be greater than a preset index threshold. Here, the index includes a bias voltage of the power amplifier or an operation current of the power amplifier.

It should be noted that as shown in FIG. 4, at least one power amplifier may be included in each of the first stage power amplification circuit 302 and the second stage power amplification circuit 304. That is, at least two power amplifiers may be included in the circuit for protecting the power amplifier provided in the embodiment of the disclosure, several power amplifiers connected before the inter-stage adjustment circuit 303 constitute the first stage power amplification circuit 302, and several power amplifiers connected after the inter-stage adjustment circuit 303 constitute the second stage power amplification circuit 304. Furthermore, it should be noted that with respect to the several power amplifiers, the embodiment of the disclosure may also connect an inter-stage adjustment circuit in series between every two adjacent power amplifiers, or connect an inter-stage adjustment circuit in series between part of the power amplifiers, to avoid burning out the power amplifiers, which is not specifically limited in the embodiment of the disclosure.

It should also be noted that the overload detection circuit 3012 detects index of each power amplifier in the target power amplification circuit, here, detection of the index of the power amplifier mainly includes the following aspects. The bias voltage or operation current of the power amplifier is detected. When it is detected that the index of any power amplifier in the target power amplification circuit is greater than the preset index threshold, it indicates overload of the power amplifier, that is, it determines overload of the target power amplification circuit to which the power amplifier belongs.

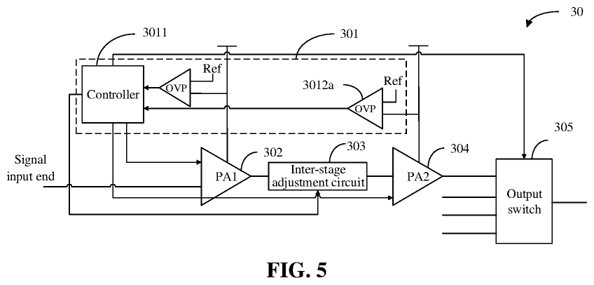

Furthermore, when the index is the bias voltage of the power amplifier, the overload detection circuit is an overvoltage detection circuit. Specifically, with reference to FIG. 5, a first schematic diagram of circuit structures of a circuit 30 for protecting a power amplifier according to an embodiment of the disclosure is shown. In some embodiments, the overload detection circuit 3012 includes an overvoltage detection circuit 3012a.

The overvoltage detection circuit 3012a is configured to compare the bias voltage of the power amplifier in the target power amplification circuit with a preset voltage threshold, and send an overvoltage signal to the controller 3011 when the bias voltage is greater than the preset voltage threshold.

The controller 3011 is specifically configured to send a first protection signal to the target power amplification circuit when the overvoltage signal is received, here, the first protection signal is configured to indicate overvoltage of the target power amplification circuit, so as to enable the overload protection of the target power amplification circuit.

It should be noted that the circuit 30 for protecting the power amplifier shown in FIG. 5 includes a controller 3011, an overvoltage detection circuit 3012a (OVP), a first stage power amplification circuit 302, an inter-stage adjustment circuit 303, a second stage power amplification circuit 304, and an output switch 305. Here, the controller 3011 is connected to the overvoltage detection circuit 3012a, the first stage power amplification circuit 302, the inter-stage adjustment circuit 303, the second stage power amplification circuit 304 and the output switch 305 respectively, so as to receive an overvoltage signal sent by the overvoltage detection circuit 3012a, and send different control signals to the first stage power amplification circuit 302, the inter-stage adjustment circuit 303, the second stage power amplification circuit 304 and the output switch 305 respectively, thereby implementing control of these devices. The overvoltage detection circuit 3012a is connected between the target power amplification circuit and the controller 3011, to implement overvoltage detection of the target power amplification circuit. The inter-stage adjustment circuit 303 is connected between an output end of the first stage power amplification circuit 302 and an input end of the second stage power amplification circuit 304, and when the inter-stage adjustment circuit 303 is turned on, the inter-stage adjustment circuit 303 transmits a signal amplified by the first stage power amplification circuit 302 to the second stage power amplification circuit 304. The output switch 305 is connected to an output end of the second stage power amplification circuit 304 and outputs a signal amplified by the second stage power amplification circuit 304.

As shown in FIG. 5, each of the first stage power amplification circuit 302 and the second stage power amplification circuit 304 including a power amplifier is taken for exemplary description, here, the first stage power amplification circuit 302 includes a power amplifier PA1, and the second stage power amplification circuit 304 includes a power amplifier PA2. During normal operation of the circuit 30 for protecting the power amplifier, the inter-stage adjustment circuit 303 is in a turn-on state, an input signal enters the circuit 30 for protecting the power amplifier from a signal input end and then is amplified by the first stage power amplification circuit 302, the first stage power amplification circuit 302 transmits an amplified input signal to the second stage power amplification circuit 304 through the inter-stage adjustment circuit 303, the amplified input signal is amplified by the second stage power amplification circuit 304, and then is output through the output switch 305.

The overvoltage detection circuit 3012a connected to each of the first stage power amplification circuit 302 and the second stage power amplification circuit 304 compares bias voltages of power amplifiers in the power amplification circuits connected thereto with their respective preset voltage thresholds (Ref), and when the bias voltage of the power amplifier is detected to be greater than the preset voltage threshold, an overvoltage signal is sent to the controller 3011. Furthermore, the embodiment of the disclosure may connect an overvoltage detection circuit 3012a to each power amplifier in the circuit, to determine whether overvoltage of the power amplifier occurs. Preset voltage thresholds of different power amplifiers may be determined in combination with performance of the power amplifiers or actual usage requirements, and may be the same or different, which is not specifically limited in the embodiment of the disclosure.

The controller 3011 sends the first protection signal to the target power amplification circuit when the overvoltage signal is received, the first protection signal is configured to indicate overvoltage of the target power amplification circuit, so as to enable the overload protection of the target power amplification circuit.

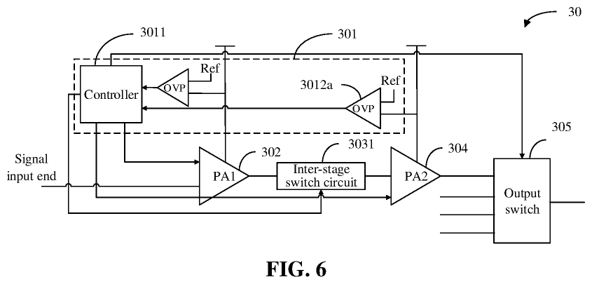

In a specific embodiment, when the inter-stage adjustment circuit 303 is an inter-stage switch circuit 3031, with reference to FIG. 6, a second schematic diagram of circuit structures of a circuit 30 for protecting a power amplifier according to an embodiment of the disclosure is shown.

As shown in FIG. 6, the inter-stage adjustment circuit 303 is specifically an inter-stage switch circuit 3031, which is different from circuit structures shown in FIG. 5. The rest of circuit structures of FIG. 6 are identical to those of FIG. 5, and may not be elaborated here. Specific operation mode of the inter-stage adjustment circuit may refer to the aforementioned descriptions, and may not be elaborated here.

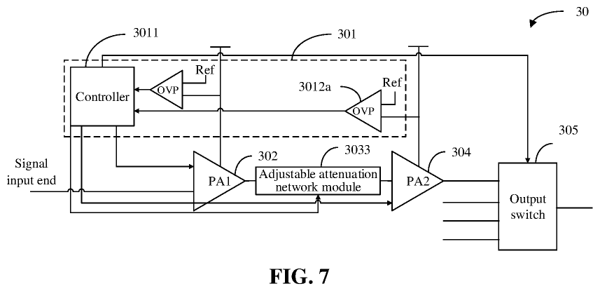

In another specific embodiment, when the inter-stage adjustment circuit 303 is an adjustable attenuation network module 3032, with reference to FIG. 7, a third schematic diagram of circuit structures of a circuit 30 for protecting a power amplifier according to an embodiment of the disclosure is shown.

As shown in FIG. 7, the inter-stage adjustment circuit 303 is specifically an adjustable attenuation network module 3032, which is different from circuit structures shown in FIG. 5. The rest of circuit structures of FIG. 7 are identical to those of FIG. 5, and may not be elaborated here. Specific operation mode of the inter-stage adjustment circuit may refer to the aforementioned descriptions, and may not be elaborated here.

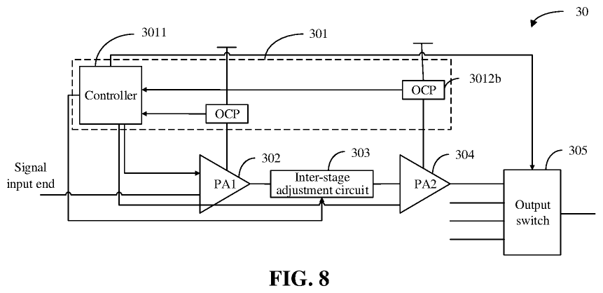

Furthermore, when the index is the operation current of the power amplifier, the overload detection circuit is an overcurrent detection circuit. Specifically, with reference to FIG. 8, a fourth schematic diagram of circuit structures of a circuit 30 for protecting a power amplifier according to an embodiment of the disclosure is shown. In some embodiments, the overload detection circuit 3012 includes an overcurrent detection circuit 3012b.

The overcurrent detection circuit 3012b is configured to compare the operation current of the power amplifier in the target power amplification circuit with a preset current threshold, and send an overcurrent signal to the controller 3011 when the operation current is greater than the preset current threshold.

The controller 3011 is specifically configured to send a second protection signal to the target power amplification circuit when the overcurrent signal is received, here, the second protection signal is configured to indicate overcurrent of the target power amplification circuit, so as to enable the overload protection of the target power amplification circuit.

It should be noted that the circuit 30 for protecting the power amplifier shown in FIG. 8 includes a controller 3011, an overcurrent detection circuit 3012b, a first stage power amplification circuit 302, an inter-stage adjustment circuit 303, a second stage power amplification circuit 304, and an output switch 305. Here, the controller 3011 is connected to the overcurrent detection circuit 3012b (OCP), the first stage power amplification circuit 302, the inter-stage adjustment circuit 303, the second stage power amplification circuit 304 and the output switch 305 respectively, so as to receive an overcurrent signal sent by the overcurrent detection circuit 3012b, and send different control signals to the first stage power amplification circuit 302, the inter-stage adjustment circuit 303, the second stage power amplification circuit 304 and the output switch 305 respectively, thereby implementing control of these devices. The overcurrent detection circuit 3012b is connected between the target power amplification circuit and the controller 3011, to implement overcurrent detection of the target power amplification circuit. The inter-stage adjustment circuit 303 is connected between an output end of the first stage power amplification circuit 302 and an input end of the second stage power amplification circuit 304, and when the inter-stage adjustment circuit 303 is turned on, the inter-stage adjustment circuit 303 transmits a signal amplified by the first stage power amplification circuit 302 to the second stage power amplification circuit 304. The output switch 305 is connected to an output end of the second stage power amplification circuit 304 and outputs a signal amplified by the second stage power amplification circuit 304.

As shown in FIG. 8, each of the first stage power amplification circuit 302 and the second stage power amplification circuit 304 including a power amplifier is taken for exemplary description, here, the first stage power amplification circuit 302 includes a power amplifier PA1, and the second stage power amplification circuit 304 includes a power amplifier PA2. During normal operation of the circuit 30 for protecting the power amplifier, the inter-stage adjustment circuit 303 is in a turn-on state, an input signal enters the circuit 30 for protecting the power amplifier from a signal input end and then is amplified by the first stage power amplification circuit 302, the first stage power amplification circuit 302 transmits an amplified input signal to the second stage power amplification circuit 304 through the inter-stage adjustment circuit 303, the amplified input signal is amplified by the second stage power amplification circuit 304, and then is output through the output switch 305.

The overcurrent detection circuit 3012b connected to each of the first stage power amplification circuit 302 and the second stage power amplification circuit 304 determines whether operation currents of power amplifiers in the power amplification circuits are too large, and when the operation current of the power amplifier is detected to be greater than the preset current threshold, an overcurrent signal is sent to the controller 3011. Furthermore, the embodiment of the disclosure may connect an overcurrent detection circuit 3012b to each power amplifier in the circuit, to determine whether overcurrent of the power amplifier occurs. Preset current thresholds of different power amplifiers may be determined in combination with performance of the power amplifiers or actual usage requirements, and may be the same or different, which is not specifically limited in the embodiment of the disclosure.

The controller 3011 sends the second protection signal to the target power amplification circuit when the overcurrent signal is received, the second protection signal is configured to indicate overcurrent of the target power amplification circuit, so as to enable the overload protection of the target power amplification circuit.

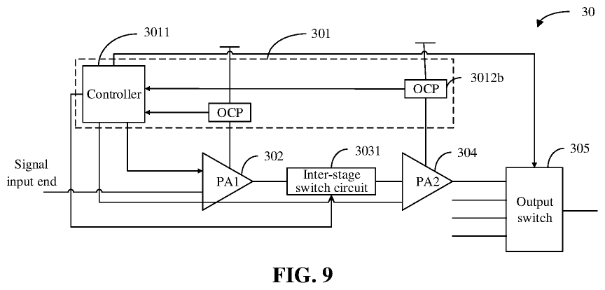

In a specific embodiment, when the inter-stage adjustment circuit 303 is an inter-stage switch circuit 3031, with reference to FIG. 9, a fifth schematic diagram of circuit structures of a circuit 30 for protecting a power amplifier according to an embodiment of the disclosure is shown.

As shown in FIG. 9, the inter-stage adjustment circuit 303 is specifically an inter-stage switch circuit 3031, which is different from circuit structures shown in FIG. 8. The rest of circuit structures of FIG. 9 are identical to those of FIG. 8, and may not be elaborated here. Specific operation mode of the inter-stage adjustment circuit may refer to the aforementioned descriptions, and may not be elaborated here.

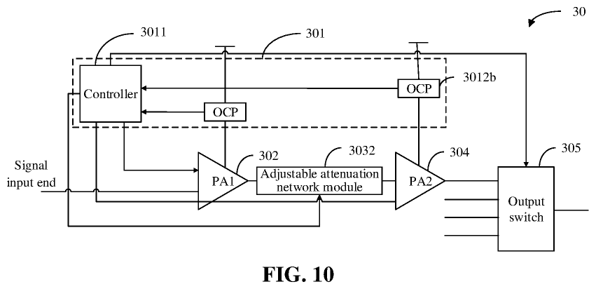

In another specific embodiment, when the inter-stage adjustment circuit 303 is an adjustable attenuation network module 3032, with reference to FIG. 10, a sixth schematic diagram of circuit structures of a circuit 30 for protecting a power amplifier according to an embodiment of the disclosure is shown.

As shown in FIG. 10, the inter-stage adjustment circuit 303 is specifically an adjustable attenuation network module 3032, which is different from circuit structures shown in FIG. 8. The rest of circuit structures of FIG. 10 are identical to those of FIG. 8, and may not be elaborated here. Specific operation mode of the inter-stage adjustment circuit may refer to the aforementioned descriptions, and may not be elaborated here.

In short, the circuit for protecting the power amplifier provided in the embodiment of the disclosure adds an inter-stage adjustment circuit between stages of the power amplification circuit. When the circuit for protecting the power amplifier operates normally, the inter-stage adjustment circuit is in a turn-on state. When the overvoltage protection or overcurrent protection is enabled, the protection control circuit lowers bias of the power amplifier or turns off the power amplifier, while controls the inter-stage adjustment circuit to be in a turn-off state. At this time, power of the input signal increases continuously due to closed-loop control of the signal. After overvoltage or overcurrent is recovered, that is, after the overvoltage protection or overcurrent protection is closed, the protection control circuit first controls recovery of bias in the circuit for protecting the power amplifier (RF path), and RF devices in the path (such as the power amplifier) returns to normal operation. At this time, even though large power is input, since the inter-stage adjustment circuit is in the turn-off state, a power amplification circuit after the inter-stage adjustment circuit may not bear the large power. In an unsteady state stage during a period when the steady state is established, the power amplifier may not be burned out. After a long enough delay (i.e., after a preset time), the power amplifier and other devices in the RF path reach their respective steady states, and the protection control circuit turns on the inter-stage adjustment circuit at this time. Since the steady state of the RF path has been established at this time, it is ensured that incoming of the input signal may not burn out the power amplifier.

The embodiment provides a circuit for protecting a power amplifier, taking a two-stage power amplification circuit as an example, the circuit for protecting the power amplifier includes a protection control circuit, an inter-stage adjustment circuit, a first stage power amplification circuit and a second stage power amplification circuit. The inter-stage adjustment circuit is connected in series between the first stage power amplification circuit and the second stage power amplification circuit. The protection control circuit is configured to: control the inter-stage adjustment circuit to be in a turn-off state when overload protection of the first stage power amplification circuit or the second stage power amplification circuit is enabled; and control the inter-stage adjustment circuit to be in a turn-on state, after a preset time elapses from the overload protection of the first stage power amplification circuit or the second stage power amplification circuit being closed. In this way, since the inter-stage adjustment circuit is turned off when the overload protection is performed on the power amplification circuit, and the inter-stage adjustment circuit is turned on after a preset time elapses from the overload protection being closed, such that the circuit for the power amplifier may be effectively protected, ensuring that a phenomenon where the power amplifier is burnt out due to excessive input power in an unsteady state stage of the circuit for the power amplifier after the overload protection is closed may not occur, while ensuring that incoming of the input signal may not burn out the power amplifier after the circuit returns to the steady state.

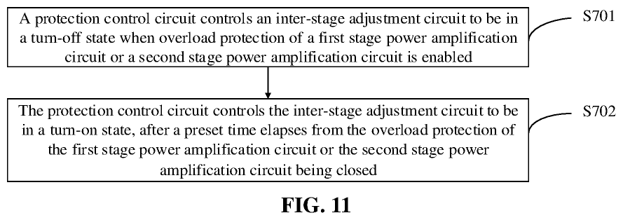

In another embodiment of the disclosure, with reference to FIG. 11, a schematic flowchart of a method for protecting a power amplifier according to an embodiment of the disclosure is shown. Taking a two-stage power amplification circuit as an example, as shown in FIG. 11, the method may include the following operations S701 to S702.

In operation S701, a protection control circuit controls an inter-stage adjustment circuit to be in a turn-off state when overload protection of a first stage power amplification circuit or a second stage power amplification circuit is enabled.

In operation S702, the protection control circuit controls the inter-stage adjustment circuit to be in a turn-on state, after a preset time elapses from the overload protection of the first stage power amplification circuit or the second stage power amplification circuit being closed.

It should be noted that when the method is applied to a multi-stage power amplification circuit, the method may include the following operations.

The protection control circuit controls the inter-stage adjustment circuit to be in a turn-off state when overload protection of any stage power amplification circuit is enabled.

In some embodiments, the protection control circuit controls the inter-stage adjustment circuit to be in a turn-on state, after a preset time elapses from the overload protection of the power amplification circuit being closed.

It should also be noted that the method may be applied to the circuit for protecting the power amplifier described in any one of the forgoing embodiments.

In some embodiments, the protection control circuit includes a controller and an overload detection circuit, and the method may further include the following operations.

The overload detection circuit detects a target power amplification circuit, outputs an overload signal and send the overload signal to the controller, when overload of the target power amplification circuit is detected.

The controller receives the overload signal and sends a protection signal to the target power amplification circuit, to enable overload protection of the target power amplification circuit.

Here, the target power amplification circuit is the first stage power amplification circuit or the second stage power amplification circuit.

In some embodiments, the protection signal is configured to instruct the target power amplification circuit to perform at least one of:
reducing a DC operation point of a power amplifier in the target power amplification circuit; or
turning off the power amplifier in the target power amplification circuit.

In some embodiments, the target power amplification circuit includes at least one power amplifier. The operation of the overload detection circuit detecting the target power amplification circuit includes the following operations.

The overload detection circuit detects index of the power amplifier in the target power amplification circuit, and determines overload of the target power amplification circuit when index of any power amplifier in the target power amplification circuit is detected to be greater than a preset index threshold.

Here, the index includes a bias voltage of the power amplifier or an operation current of the power amplifier.

In some embodiments, the overload detection circuit includes an overvoltage detection circuit. The operation of the overload detection circuit detecting the target power amplification circuit, outputting the overload signal and send the overload signal to the controller, when overload of the target power amplification circuit is detected may include the following operations.

The overvoltage detection circuit compares the bias voltage of the power amplifier in the target power amplification circuit with a preset voltage threshold, and sends an overvoltage signal to the controller when the bias voltage is greater than the preset voltage threshold.

The operation of the controller receiving the overload signal and sending the protection signal to the target power amplification circuit, to enable overload protection of the target power amplification circuit may include the following operations.

The controller receives the overvoltage signal and sends a first protection signal to the target power amplification circuit, here, the first protection signal is configured to indicate overvoltage of the target power amplification circuit, so as to enable the overload protection of the target power amplification circuit.

In some embodiments, the overload detection circuit includes an overcurrent detection circuit. The operation of the controller receiving the overload signal and sending the protection signal to the target power amplification circuit, to enable overload protection of the target power amplification circuit may include the following operations.

The overcurrent detection circuit compares the operation current of the power amplifier in the target power amplification circuit with a preset current threshold, and sends an overcurrent signal to the controller when the operation current is greater than the preset current threshold.

The operation of the controller receiving the overload signal and sending the protection signal to the target power amplification circuit, to enable overload protection of the target power amplification circuit may include the following operations.

The controller receives the overcurrent signal, sends a second protection signal to the target power amplification circuit, here, the second protection signal is configured to indicate overcurrent of the target power amplification circuit, so as to enable the overload protection of the target power amplification circuit.

In some embodiments, the method may further include the following operations.

The controller sends a recovery signal to the target power amplification circuit, to close the overload protection of the target power amplification circuit.

Here, the recovery signal is configured to instruct the target power amplification circuit to perform at least one of:
recovering a DC operation point of a power amplifier in the target power amplification circuit; or
turning on the power amplifier in the target power amplification circuit.

In some embodiments, the preset time indicates a delay time required for each device in the circuit for protecting the power amplifier to reach a steady state, after the overload protection of the first stage power amplification circuit or the second stage power amplification circuit is closed.

In some embodiments, the method may further include the following operations.

The protection control circuit controls the inter-stage adjustment circuit to be in the turn-on state during normal operation of the circuit for protecting the power amplifier.

In some embodiments, the inter-stage adjustment circuit is an inter-stage switch circuit or an adjustable attenuation network module.

In some embodiments, the inter-stage adjustment circuit is the inter-stage switch circuit, and the inter-stage switch circuit includes a switch. The operation of the protection control circuit controlling the inter-stage adjustment circuit to be in the turn-off state includes the following operations.

The protection control circuit controls the switch to be turned off, such that the inter-stage adjustment circuit is in the turn-off state.

The operation of the protection control circuit controlling the inter-stage adjustment circuit to be in the turn-on state, after the preset time elapses includes the following operations.

The protection control circuit controls the switch to be turned on, after a preset time elapses, such that the inter-stage adjustment circuit is in the turn-on state.

In some embodiments, the inter-stage adjustment circuit is the adjustable attenuation network module, and the adjustable attenuation network module is configured to characterize a state change of the inter-stage adjustment circuit by adjusting an insertion loss itself.

Here, the operation of the protection control circuit controlling the inter-stage adjustment circuit to be in the turn-off state includes the following operations.

The protection control circuit controls the insertion loss of the adjustable attenuation network module to be in a first insertion loss state, such that the inter-stage adjustment circuit is in the turn-off state.

The operation of the protection control circuit controlling the inter-stage adjustment circuit to be in the turn-on state, after the preset time elapses includes the following operations.

The protection control circuit controls the insertion loss of the adjustable attenuation network module to be in a second insertion loss state, after a preset time elapses, such that the inter-stage adjustment circuit is in the turn-on state.

Here, the insertion loss in the first insertion loss state is greater than the insertion loss in the second insertion loss state.

It may be understood that the method for protecting the power amplifier provided in the embodiment of the disclosure belongs to the same inventive concept as the circuit for protecting the power amplifier provided in the forgoing embodiments, has similar specific descriptions thereof, and has similar beneficial effects to the embodiments of the method. Technical details not disclosed in the embodiments of the method for protecting the power amplifier of the disclosure are understood with reference to descriptions of the embodiments of the circuit for protecting the power amplifier of the disclosure.

The embodiment provides a method for protecting a power amplifier. When the circuit for protecting the power amplifier includes a two-stage power amplification circuit, the method includes the following operations. A protection control circuit controls an inter-stage adjustment circuit to be in a turn-off state when overload protection of a first stage power amplification circuit or a second stage power amplification circuit is enabled. The protection control circuit controls the inter-stage adjustment circuit to be in a turn-on state, after a preset time elapses from the overload protection of the first stage power amplification circuit or the second stage power amplification circuit being closed. In this way, since the inter-stage adjustment circuit is turned off when the overload protection is performed on the power amplification circuit, and the inter-stage adjustment circuit is turned on after a preset time elapses from the overload protection being closed, such that the circuit for the power amplifier may be effectively protected, ensuring that a phenomenon where the power amplifier is burnt out due to excessive input power in an unsteady state stage of the circuit for the power amplifier after the overload protection is closed may not occur, while ensuring that incoming of the input signal may not burn out the power amplifier after the circuit returns to the steady state, so that damage of the power amplifier due to excessive input power is avoided, thereby achieving a function of protecting the power amplifier.

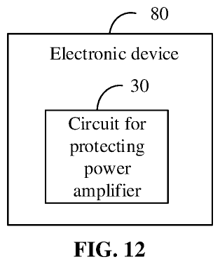

In yet another embodiment of the disclosure, with reference to FIG. 12, a schematic diagram of compositional structures of an electronic device 80 according to an embodiment of the disclosure is shown. As shown in FIG. 12, the electronic device 80 includes at least the circuit 30 for protecting the power amplifier as described in any one of the forgoing embodiments.

Since the electronic device 80 includes the circuit 30 for protecting the power amplifier, the circuit for the power amplifier may be effectively protected, ensuring that a phenomenon where the power amplifier is burnt out due to excessive input power in an unsteady state stage of the circuit for the power amplifier after the overload protection is closed may not occur, while ensuring that the input signal may not burn out the power amplifier after the circuit returns to normal operation.

The above descriptions are only preferred embodiments of the disclosure and are not intended to limit the scope of protection of the disclosure.

It should be noted that in the disclosure, terms “including”, “include” or any other variants thereof are intended to encompass non-exclusive inclusion, to allow a process, method, article or device including a series of elements to include not only those elements, but also other elements which are not listed clearly or elements inherent to the process, method, article or device. Without further limitation, an element defined by a phrase “including a . . . ” does not preclude presence of additional identical elements in a process, method, article or device including the element.

Serial numbers of the above embodiments of the disclosure are only intended for description and do not represent advantages or disadvantages of the embodiments.

Methods disclosed in the method embodiments provided in the disclosure may be combined arbitrarily without conflict, to obtain new method embodiments.

Features disclosed in the product embodiments provided in the disclosure may be combined arbitrarily without conflict, to obtain new product embodiments.

Features disclosed in the method or device embodiments provided in the disclosure may be combined arbitrarily without conflict, to obtain new method or device embodiments.

The above descriptions are only specific implementations of the disclosure, however, the scope of protection of the disclosure is not limited thereto. Any variations or replacements apparent to those skilled in the art within the technical scope disclosed in the disclosure should fall within the scope of protection of the disclosure. Therefore, the scope of protection of the disclosure should be subjected to the scope of protection of the claims.

According to the circuit and method for protecting the power amplifier provided in the embodiments of the disclosure, the circuit for protecting the power amplifier includes a protection control circuit, an inter-stage adjustment circuit and a multi-stage power amplification circuit. The inter-stage adjustment circuit is connected in series between at least two adjacent power amplification circuits in the multi-stage power amplification circuit. The protection control circuit is configured to: control the inter-stage adjustment circuit to be in a turn-off state when overload protection of a first stage power amplification circuit or a second stage power amplification circuit is enabled; and control the inter-stage adjustment circuit to be in a turn-on state, after a preset time elapses from the overload protection of the first stage power amplification circuit or the second stage power amplification circuit being closed. In this way, it is ensured that the power amplifier may not be damaged due to excessive input power in a process of establishing a steady state of the circuit, and that incoming of the input signal may not burn out the power amplifier after the circuit returns to the steady state, such that damage of the power amplifier due to excessive input power is avoided, thereby achieving a function of protecting the power amplifier.

1. A circuit for protecting a power amplifier, comprising: a protection control circuit, an inter-stage adjustment circuit and a multi-stage power amplification circuit, the inter-stage adjustment circuit connected in series between at least two adjacent power amplification circuits in the multi-stage power amplification circuit,
wherein the protection control circuit is configured to:
control the inter-stage adjustment circuit to be in a turn-off state when overload protection of any stage power amplification circuit is enabled; and
control the inter-stage adjustment circuit to be in a turn-on state, after a preset time elapses from the overload protection of the power amplification circuit being closed.

2. The circuit for protecting the power amplifier of claim 1, wherein the inter-stage adjustment circuit is arranged between at least last two stage power amplification circuits in the multi-stage power amplification circuit.

3. The circuit for protecting the power amplifier of claim 1, wherein the inter-stage adjustment circuit is arranged between every two adjacent stage power amplification circuits in the multi-stage power amplification circuit.

4. The circuit for protecting the power amplifier of claim 1, wherein the protection control circuit comprises a controller and an overload detection circuit,
the overload detection circuit is configured to output an overload signal and send the overload signal to the controller, when overload of a target power amplification circuit is detected,
the controller is configured to send a protection signal to the target power amplification circuit when the overload signal is received, to enable overload protection of the target power amplification circuit.

5. The circuit for protecting the power amplifier of claim 4, wherein the protection signal is configured to instruct the target power amplification circuit to perform at least one of:
reducing a direct current (DC) operation point of a power amplifier in the target power amplification circuit; or
turning off the power amplifier in the target power amplification circuit.

6. The circuit for protecting the power amplifier of claim 4, wherein the target power amplification circuit comprises at least one power amplifier,
the overload detection circuit is specifically configured to detect index of the power amplifier in the target power amplification circuit, and determine overload of the target power amplification circuit when index of any power amplifier in the target power amplification circuit is detected to be greater than a preset index threshold,
wherein the index comprises a bias voltage of the power amplifier or an operation current of the power amplifier.

7. The circuit for protecting the power amplifier of claim 6, wherein the overload detection circuit comprises an overvoltage detection circuit,
the overvoltage detection circuit is configured to compare the bias voltage of the power amplifier in the target power amplification circuit with a preset voltage threshold, and send an overvoltage signal to the controller when the bias voltage is greater than the preset voltage threshold,
the controller is specifically configured to send a first protection signal to the target power amplification circuit when the overvoltage signal is received, wherein the first protection signal is configured to indicate overvoltage of the target power amplification circuit, so as to enable the overload protection of the target power amplification circuit.

8. The circuit for protecting the power amplifier of claim 6, wherein the overload detection circuit comprises an overcurrent detection circuit,
the overcurrent detection circuit is configured to compare the operation current of the power amplifier in the target power amplification circuit with a preset current threshold, and send an overcurrent signal to the controller when the operation current is greater than the preset current threshold,
the controller is specifically configured to send a second protection signal to the target power amplification circuit when the overcurrent signal is received, wherein the second protection signal is configured to indicate overcurrent of the target power amplification circuit, so as to enable the overload protection of the target power amplification circuit.

9. The circuit for protecting the power amplifier of claim 4, wherein the controller is further configured to send a recovery signal to the target power amplification circuit, to close the overload protection of the target power amplification circuit,
the recovery signal is configured to instruct the target power amplification circuit to perform at least one of:
recovering a direct current (DC) operation point of a power amplifier in the target power amplification circuit; or
turning on the power amplifier in the target power amplification circuit.

10. The circuit for protecting the power amplifier of claim 1, wherein the preset time indicates a delay time required for each device in the circuit for protecting the power amplifier to reach a steady state, after the overload protection of the power amplification circuit is closed.

11. The circuit for protecting the power amplifier of claim 1, wherein the protection control circuit is further configured to control the inter-stage adjustment circuit to be in the turn-on state during normal operation of the circuit for protecting the power amplifier.

12. The circuit for protecting the power amplifier of claim 1, wherein the inter-stage adjustment circuit is an inter-stage switch circuit or an adjustable attenuation network module.

13. The circuit for protecting the power amplifier of claim 12, wherein the inter-stage adjustment circuit is the inter-stage switch circuit, and the inter-stage switch circuit comprises a switch,
the protection control circuit is specifically configured to:
control the switch to be turned off when overload protection of a target power amplification circuit is enabled, such that the inter-stage adjustment circuit is in the turn-off state; and
control the switch to be turned on, after a preset time elapses from the overload protection of the target power amplification circuit being closed, such that the inter-stage adjustment circuit is in the turn-on state.

14. The circuit for protecting the power amplifier of claim 12, wherein the inter-stage adjustment circuit is the adjustable attenuation network module, and the adjustable attenuation network module is configured to characterize a state change of the inter-stage adjustment circuit by adjusting an insertion loss itself,
the protection control circuit is specifically configured to:
control the insertion loss of the adjustable attenuation network module to be in a first insertion loss state when overload protection of a target power amplification circuit is enabled, such that the inter-stage adjustment circuit is in the turn-off state; and
control the insertion loss of the adjustable attenuation network module to be in a second insertion loss state, after a preset time elapses from the overload protection of the target power amplification circuit being closed, such that the inter-stage adjustment circuit is in the turn-on state,
wherein the insertion loss in the first insertion loss state is greater than the insertion loss in the second insertion loss state.

15. A method for protecting a power amplifier, comprising:
controlling, by a protection control circuit, an inter-stage adjustment circuit to be in a turn-off state when overload protection of any stage power amplification circuit is enabled; and
controlling, by the protection control circuit, the inter-stage adjustment circuit to be in a turn-on state, after a preset time elapses from the overload protection of the power amplification circuit being closed.
